(19) United States
(12) Patent Application Publication
(10) Pub. No.: US 2012/0276291 A1
(43) Pub. Date: Nov. 1, 2012

(54) Methods and Apparatuses for Reducing Gelation of Glass Precursor Materials During Vaporization

(76) Inventors: Chester D. Bird, Mint Hill, NC (US); Dale Robert Powers, Elmira, NY (US); Pushkar Tandon, Painted Post, NY (US); Srinivas Vemury, Wilmington, NC (US)

(21) Appl. No.: 13/096,264

(22) Filed: Apr. 28, 2011

(51) Int. Cl. C23C 16/448; C23C 16/52

(52) U.S. Cl. 427/248.1; 118/726; 118/666

(57) ABSTRACT

Methods and apparatuses for vaporizing liquid precursor material for use in a vapor deposition process are disclosed. The method for vaporizing liquid precursor material includes introducing a flow of liquid precursor material into an expansion chamber and directing the flow of liquid precursor material towards a wall of the chamber. The wall of the chamber is heated to a temperature sufficient to vaporize a first portion of the flow of liquid precursor material while a second portion of the flow of liquid precursor material remains in a liquid state and a third portion of the liquid precursor material is formed into gel. The expansion chamber is continuously drained as the flow of liquid precursor material is introduced into the expansion chamber. The chamber is heated to a temperature to produce a sufficient amount of the second portion of the liquid precursor material to flush the gel from the chamber.

### BACKGROUND

1. Field

The present specification generally relates to methods and systems for the vapor deposition of glass precursor materials and, more specifically, to methods and systems for reducing gelation during vaporization of glass precursor materials in the manufacture of optical fiber preforms.

2. Technical Background

Glass optical fiber is generally formed by drawing the optical fiber from a glass preform. The glass preform may be formed by depositing silica glass soot on a bait rod or core cane by vapor deposition. Halide free cyclo-siloxanes, such as octamethylcyclotetracyloxane (OMCTS) are commonly used as liquid precursor materials for producing pyrogenically generated silica particles which are deposited on the bait rod to form the optical fiber preform. The liquid precursors are vaporized in a vaporizer and then fed to a burner, where they undergo an oxidation reaction at the high temperature of the burner to form silica glass soot.

During the vaporization process, impurities in the liquid precursor materials can polymerize in the vaporizer and result in the formation of a gel which collects in the lower regions of the vaporizer. Such impurities include, for example, high molecular weight siloxanes, non-volatile residues, amines, silanols, silanes, acids (e.g., HCl), bases (e.g., NaOH, KOH), dissolved oxygen, and the like. Moreover, some of the liquid precursor materials may not undergo vaporization in the vaporizer and pools in the lower region of the vaporizer where it may gel, further fouling the interior of the vaporizer. Excessive pooling of the precursor material in the vaporizer and the subsequent gelation increases the back pressure in the vaporizer and diminishes system performance. Accordingly, frequent cleaning of the vaporizer is needed to mitigate these issues. Frequent cleaning of the vaporizer requires equipment down time and, as a result, adversely impacts manufacturing productivity as the formation of optical fiber preforms may be performed as a continuous process.

### SUMMARY

According to one embodiment, a method for vaporizing liquid precursor material for use in a vapor deposition process includes introducing a flow of liquid precursor material into an expansion chamber, the liquid precursor material being polymerizable to form a gel. The flow of liquid precursor material is directed towards a vertical wall of the expansion chamber. The vertical wall of the expansion chamber is heated to a temperature sufficient to vaporize a first portion of the flow of liquid precursor material while a second portion of the flow of liquid precursor material remains in a liquid state and a third portion of the liquid precursor material is formed into the gel. The gel is collected at a lower region of the expansion chamber. The expansion chamber is continuously drained as the flow of liquid precursor material is introduced into the expansion chamber. The expansion chamber is heated to a temperature such that a sufficient amount of the liquid precursor material is present to continuously flush the gel from the expansion chamber.

In another embodiment, a method for vaporizing liquid precursor material for use in a vapor deposition process includes introducing a flow of liquid precursor material into an expansion chamber, a, portion of the liquid precursor material being polymerizable to form a gel. A flow of the liquid precursor material is directed towards a wall of the expansion chamber. The wall of the expansion chamber is heated to a temperature sufficient to vaporize a first portion of the flow of liquid precursor material while a second portion of the flow of liquid precursor material remains in a liquid state and a third portion of the liquid precursor material is formed into the gel and the temperature satisfies the relationship:

$$P = A exp ( - \frac{B}{T + D} ) ,$$

wherein T is the temperature of the expansion chamber, P is a pressure inside the expansion chamber, and A, B and D are parameters that describe a vapor pressure of a species in the flow of the liquid precursor material to be vaporized.

According to another embodiment, a vaporizer for vaporizing liquid precursor material used in the formation of glass optical fiber preforms includes a first expansion chamber at least partially enclosed by a first vertical wall, the first expansion chamber formed from a material having a thermal conductivity of at least 100 BTU/hr-ft-F. A first liquid delivery conduit may be positioned in the first expansion chamber such that the first liquid delivery conduit directs a spray of liquid precursor materials onto the first vertical wall. A first vapor delivery conduit is fluidly coupled to the first expansion chamber such that the first vapor delivery conduit extracts vaporized liquid precursor material from the first expansion chamber. A first stirring apparatus may be disposed within the first expansion chamber, such that the first stirring apparatus stirs the vaporized liquid precursor material such that a temperature of the vaporized liquid precursor material is uniform within the first expansion chamber. A heating system may be thermally coupled to the first vertical wall of the first expansion chamber, the heating system heating at least a portion of the first vertical wall to a temperature sufficient to vaporize the liquid precursor material.

Additional features and advantages of the invention will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a vaporizer according to one or more embodiments shown and described herein; and

FIG. 2 schematically depicts a vaporizer with dual expansion chambers according to one or more embodiments shown and described herein.

### DETAILED DESCRIPTION

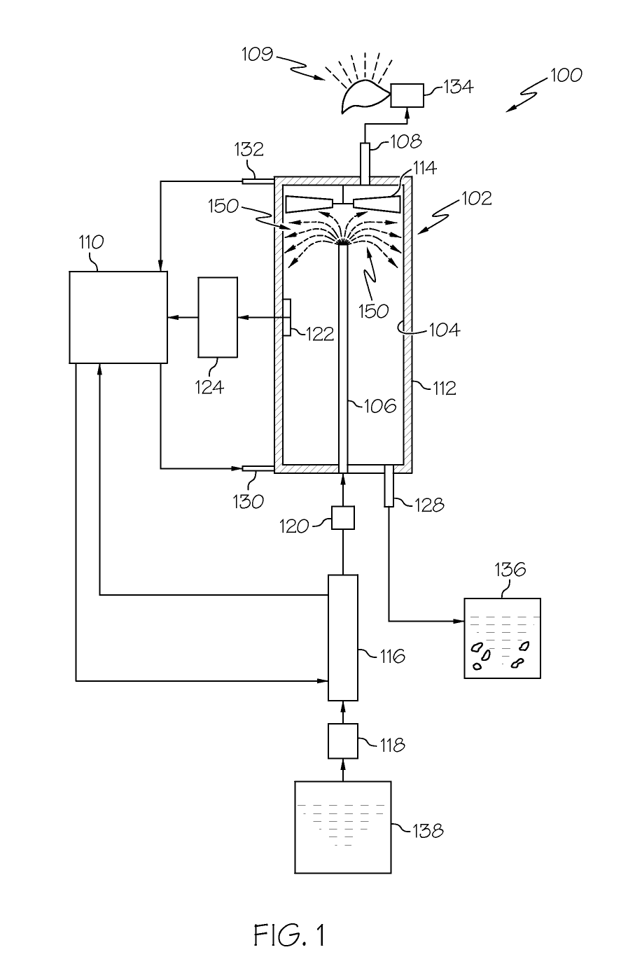

Reference will now be made in detail to embodiments of vaporizers and methods of utilizing the same. FIG. 1 generally depicts one embodiment of a vaporizer according to one or more embodiments shown and described herein. The vaporizer generally comprises an expansion chamber at least partially enclosed by a vertical wall, a liquid delivery conduit, a vapor delivery conduit, a stirring mechanism and a heating system. The vaporizer may be operated at a temperature such that a first portion of liquid precursor material is converted to vapor, a second portion of the liquid precursor material remains in the liquid state and a third portion of the liquid precursor material forms a gel. A sufficient amount of the liquid precursor material remains in the liquid state to facilitate continuously flushing the gel from the expansion chamber while at least a first portion of the liquid precursor material is converted to vapor. The vaporizer and methods of operating the vaporizer will be described in more detail herein.

Reference will be made herein to the use of a “liquid precursor material” in conjunction with various embodiments of vaporizers for forming optical fiber preforms. In these embodiments, “liquid precursor materials” refers to octymethylcyclotetrasiloxane (OMCTS) as well as various other siloxane species and impurities which may be present in the OMCTS when delivered to the vaporizer system in liquid form.

Reference will also be made herein to first, second and third portions of the liquid precursor material. In one embodiment described herein the first portion of the liquid precursor material is OMCTS, also referred to as D₄, where D represents the group ([(CH₃)₂Si]—O—). The second portion of the liquid precursor material is a mixture of OMCTS with other siloxane species which have higher boiling points such that the second portion of the liquid precursor material has a boiling point equal to or higher than that of the first portion of the liquid precursor material. In the embodiments described herein the second portion of the liquid precursor material comprises a mixture of OMCTS and other higher boiling point siloxanes. For example, the second portion of the liquid precursor material may be decamethylcyclopentasiloxane (D₅), dodecamethylcyclohexasiloxane (D₆) or Dₙ, where n is between 7 and 40. The third portion of the liquid precursor material comprises the impurities in the liquid precursor materials which polymerize (i.e., gel) in the expansion chamber of the vaporizer resulting in the fouling of the expansion chamber. In the embodiments described herein, the third portion of the liquid precursor material comprises linear siloxanes having hydroxyl endcaps with the general formula OH—[Si—(CH₃)₂-O]n-H where n>2.

Referring to FIG. 1, a vaporizer 100 generally comprises an expansion chamber 102, a heating system 110, a liquid delivery conduit 106, a vapor delivery conduit 108, a stirring mechanism 114 and a drain 128. The expansion chamber 102 is at least partially enclosed by a vertical wall 104. The expansion chamber 102 is generally formed from a material with a high thermal conductivity such that the vertical wall 104 of the expansion chamber 102 can be uniformly heated and localized “hot spots” are avoided. Hot spots in the expansion chamber 102 may overheat the liquid precursor material which leads to gelation of the liquid precursor material and fouling of the expansion chamber. To promote uniform heating, the expansion chamber 102 is formed from a material which has a thermal conductivity of greater than about 100 BTU/hr-ft-F, more preferably greater than about 150 BTU/hr-ft-F and more preferably greater than about 200 BTU/hr-ft-F. Suitable materials from which the expansion chamber 102 is formed include, without limitation, aluminum, beryllium, copper, silver, tungsten and zirconium, each of which has a thermal conductivity of at least 100 BTU/hr-ft-F at room temperature.

For example, in one embodiment the expansion chamber 102 is generally cylindrical in cross section and is constructed from 6061 aluminum to achieve the desired thermal conductivity. The inner diameter of the cylinder may be 3.5 inches (8.89 cm) and the outer diameter may be about 8.0 inches (20.32 cm). The length of the vaporizer unit may be about 38 inches (96.52 cm). However it should be understood that the expansion chamber 102 may be constructed from other materials and/or have other dimensions.

The expansion chamber 102 also includes a drain 128 in the lower region of the expansion chamber to facilitate flushing by-products of the vaporization process from the interior of the expansion chamber 102. The drain 128 is fluidly coupled to a collection reservoir 136 which collects the vaporization by-products that are flushed from the interior of the expansion chamber.

In one exemplary embodiment, the drain 128 is constructed of a 0.25 inch (0.635 cm) diameter tube have a length of 6 inches (15.24 cm). In this embodiment the drain tube is constructed from stainless steel which is curved into an s-shape. The tube is affixed to the bottom of the expansion chamber at a downward angle of approximately 45 degrees and coupled to the collection reservoir 136 with teflon tubing. A ball valve may be coupled to the drain to enable to the drain to be closed off.

In the embodiments described herein, the expansion chamber 102 further comprises a stirring mechanism 114 positioned within the expansion chamber. The stirring mechanism 114 stirs the vaporized liquid precursor material in the expansion chamber such that the temperature of the vaporized liquid precursor material is uniform within the expansion chamber thereby avoiding hot spots and mitigating the formation of the vaporized liquid precursor material into a gel. In the embodiments shown and described herein, the stirring mechanism 114 is a paddle stirrer. However, it should be understood that other stirring mechanisms may be utilized, including, without limitation, magnetic stirrers and the like. Further, while the embodiments described herein depict the stirring mechanism 114 being positioned in the upper region of the expansion chamber 102, it should be understood that the stirring mechanism 114 may be located at other locations in the expansion chamber 102 and/or that multiple stirring mechanisms may be used in the expansion chamber 102.

The vertical wall 104 of the expansion chamber 102 is thermally coupled to a heating system 110 to facilitate heating at least a portion of the vertical wall 104 to a temperature sufficient to vaporize at least a portion of the liquid precursor material which is sprayed onto the vertical wall 104. In the embodiments described herein, the heating system 110 comprises a hot oil heating system which pumps heated oil into a heating jacket 112 positioned around the expansion chamber 102. The heated oil enters the heating jacket 112 through an inlet 130 and is circulated through the expansion chamber, exiting the expansion chamber from outlet 132. The heat carried by the oil is transferred to at least a portion of the vertical wall 104 of the expansion chamber 102, thereby heating both the vertical wall 104 and the interior of the expansion chamber 102 to the desired temperature.

In one exemplary embodiment, the heating jacket 112 is integrally formed with the expansion chamber 102. For example, the expansion chamber 102 may comprise a plurality of channels (not shown) between the inner diameter and the outer diameter through which heating oil may be circulated. The channels generally extend along the length (i.e., from bottom to top) of the expansion chamber 102. In one embodiment where the expansion chamber has an outer diameter of 8.0 inches, twelve channels having a diameter of 0.63 inches (1.6 cm) are arranged in a circle having a diameter of 4.75 inches (12.065 cm). Heating oil is introduced into the channels at the bottom of the expansion chamber 102 and extracted from the channels near the top of the expansion chamber 102.

In the embodiments described herein the expansion chamber 102 may further comprise a temperature sensor 122. The temperature sensor 122 is electrically coupled to a control unit 124 which, in turn, is electrically coupled to the heating system 110. The control unit 124 comprises a processor and a memory. The memory contains computer readable and executable instructions that, when executed by the processor, may be utilized by the control unit to control the temperature of the vertical wall 104 of the expansion chamber 102 based on signals received from the temperature sensor 122. For example, the control unit 124 can receive a signal from the temperature sensor 122 indicative of the temperature of the vertical wall 104 of the expansion chamber 102. Utilizing the signal received from the temperature sensor 122, the control unit 124 provides control signals to the heating system 110 to either increase or decrease the temperature of the oil supplied to the heating jacket 112, thereby controlling the temperature of the vertical wall of the expansion chamber.

The liquid precursor material is supplied to the expansion chamber 102 with a liquid delivery conduit 106. The liquid delivery conduit 106 is positioned in the expansion chamber 102 and facilitates forming a flow of liquid precursor material into a spray which is directed towards the vertical wall 104 of the expansion chamber 102. In the embodiments described herein, the flow of liquid precursor material is converted into a spray as it passes through orifices (not shown) formed in the end of the liquid delivery conduit.

More specifically, the liquid precursor material is drawn from a fluid reservoir 138 with a metering pump 118, such as a gear pump, or any other pump having suitable flow control and appropriate size to deliver the necessary pressure. The liquid precursor material first passes through a preheater 116 which heats the liquid precursor material to a desired temperature. The preheater 116 is essentially a heating jacket formed around the supply conduit. In the embodiments of the vaporizer 100 shown and described herein, the preheater 116 is coupled to the heating system 110 and, as such, the liquid precursor material flowing through the preheater 116 is heated by oil circulated through the preheater 116 with the heating system.

While the heating system 110 and the preheater 116 have been described herein as utilizing heated oil to obtain the desired temperatures, it should be understood that other types of heating systems and/or fluids may be used to control the temperature of the vertical wall 104 of the expansion chamber 102.

When the liquid precursor material is octamethylcyclotetrasiloxane (OMCTS), the flow rate of the liquid precursor material is in the range from about 80 grams/minute to about 200 grams/minute to facilitate the production of glass preforms. In one exemplary embodiment, the preheater 116 heats the OMCTS to a temperature of approximately 195° C.±2 degrees, depending on the particular species to vaporized (described further herein). However, the boiling point of OMCTS at atmospheric pressure is 175.5° C. Accordingly, to prevent the OMCTS from boiling in the preheater, the liquid delivery conduit 106 and the metering pump 118 operate in conjunction with one another to create a backpressure of at least 10 psig, more preferably at least 15 psig, in the preheater 116, thereby lowering the boiling point of the OMCTS.

In order to achieve the desired backpressure in the preheater 116, the orifices formed in the end of the liquid delivery conduit 106 have a diameter of about 0.25 mm. In one embodiment, six orifices are formed around the circumference of the end of the liquid delivery conduit 106. This configuration of orifices has been determined to produce the desired backpressure in the preheater 116 when the liquid precursor flow rate is 80 grams/minute. A pressure sensor 120 can be disposed in the flow path of the liquid precursor material to monitor the pressure of the liquid precursor material as it is pumped from the fluid reservoir 138 into the expansion chamber 102.

Still referring to FIG. 1, the vaporizer 100 further comprises a vapor delivery conduit 108 which is fluidly coupled to the expansion chamber 102. Vaporized liquid precursor materials are extracted through the vapor delivery conduit 108 and fed to a burner 134 which pyrolizes the vaporized liquid precursor materials thereby creating silica glass soot 109 which is deposited onto a bait rod to form an optical fiber preform. In one exemplary embodiment the delivery conduit has a diameter of approximately 1 inch (2.54 cm), although delivery conduits of other dimensions may also be used.

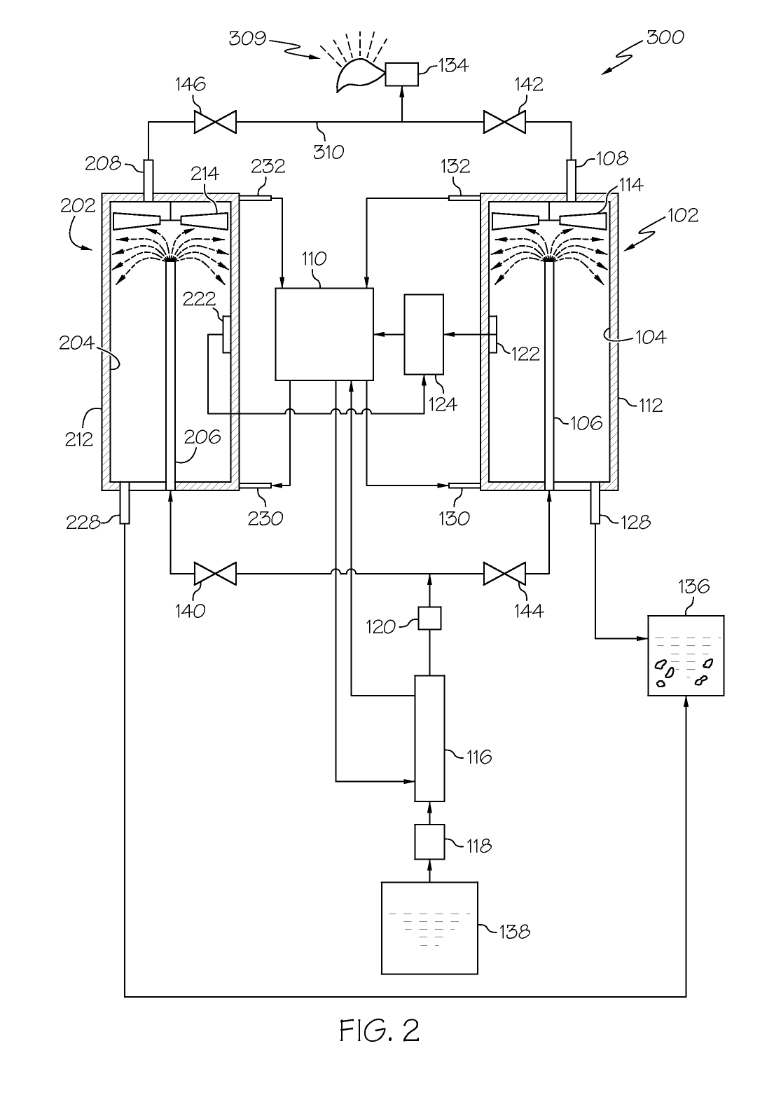

Referring now to FIG. 2, another embodiment of a vaporizer 300 is schematically depicted. In this embodiment, the vaporizer 300 comprises a first expansion chamber 102, as described above, and a second expansion chamber 202. In this embodiment, the vaporizer 300 includes all the elements of the vaporizer 100 shown in FIG. 1 in addition to the second expansion chamber 202. The first expansion chamber 102 and the second expansion chamber 202 are oriented in parallel with one another in the vaporizer 300 such that either the first expansion chamber 102 or the second expansion chamber 202 can be used to facilitate the vaporization of the liquid precursor material.

In this embodiment, the second expansion chamber 202 has a similar construction as the first expansion chamber 102. Specifically, the expansion chamber 202 is at least partially enclosed by a vertical sidewall 204. The expansion chamber 202 is generally formed from a material with a high thermal conductivity such that the vertical wall 204 of the expansion chamber 202 can be uniformly heated and localized “hot spots” are avoided. In general, the expansion chamber 202 is formed from a material which has a thermal conductivity of greater than about 100 BTU/hr-ft-F, more preferably greater than about 150 BTU/hr-ft-F and mores preferably greater than about 200 BTU/hr-ft-F.

The expansion chamber 202 also includes a drain 228 in the lower region of the expansion chamber to facilitate flushing by-products of the vaporization process from the interior of the expansion chamber 202. As with the first expansion chamber 102, the drain 228 is fluidly coupled to the collection reservoir 136 which collects the vaporization by-products that are flushed from the interior of the expansion chamber.

The expansion chamber 202 further comprises a stirring mechanism 214 positioned within the expansion chamber. The stirring mechanism 214 stirs the vaporized liquid precursor materials in the expansion chamber such that the temperature of the vaporized liquid precursor material is uniform within the expansion chamber thereby avoiding hot spots and mitigating the formation of the vaporized liquid precursor material into a gel. In the embodiments shown and described herein, the stirring mechanism 214 is a paddle stirrer. However, it should be understood that other stirring mechanisms may be utilized, including, without limitation, magnetic stirrers and the like. Further, while the embodiments described herein depict the stirring mechanism 214 being positioned in the upper region of the expansion chamber 202, it should be understood that the stirring mechanism 214 may be located at other locations in the expansion chamber 202 and/or that multiple stirring mechanisms may be used in the expansion chamber 202.

The vertical wall 204 of the expansion chamber 202 is thermally coupled to the heating system 110 to facilitate heating at least a portion of the vertical wall 204 to a temperature sufficient to vaporize at least a portion of the liquid precursor material which is sprayed onto the vertical wall 204. As described above, the heating system 110 comprises a hot oil heating system which pumps heated oil into a heating jacket 212 positioned around the expansion chamber 202. The heated oil enters the heating jacket 212 through an inlet 230 and is circulated around the expansion chamber, exiting the expansion chamber from outlet 232. The heat carried by the oil is transferred to at least a portion of the vertical wall 204 of the expansion chamber 202, thereby heating both the vertical wall 204 and the interior of the expansion chamber 202 to the desired temperature.

In the embodiments described herein the expansion chamber 202 may further comprise a temperature sensor 222, as described hereinabove with respect to the expansion chamber 102 shown in FIG. 1. The temperature sensor 222 is electrically coupled to a control unit 124 which, in turn, is electrically coupled to the heating system 110. The control unit 124 comprises a processor and a memory. The memory contains computer readable and executable instructions that, when executed by the processor, may be utilized by the control unit to control the temperature of the vertical wall 204 of the expansion chamber 202 based on signals received from the temperature sensor 222. For example, the control unit 124 can receive a signal from the temperature sensor 222 indicative of the temperature of the vertical wall 204 of the expansion chamber 202. Utilizing the signal received from the temperature sensor 222, the control unit 124 provides control signals to the heating system 110 to either increase or decrease the temperature of the oil supplied to the heating jacket 212, thereby controlling the temperature of the vertical wall of the expansion chamber.

The liquid precursor material is supplied to the expansion chamber 202 with a liquid delivery conduit 206 which is positioned in the expansion chamber 202 and facilitates forming a flow of liquid precursor material into a spray which is directed towards the vertical wall 204 of the expansion chamber 202, as described hereinabove with respect to the expansion chamber 102 depicted in FIG. 1. In the embodiments described herein, the flow of liquid precursor material is converted into a spray as it passes through orifices (not shown) formed in the end of the liquid delivery conduit.

In this embodiment, the liquid delivery conduit 106 of the first expansion chamber 102 and the liquid delivery conduit 206 of the second expansion chamber 202 are fluidly coupled to the pressure sensor 120 such that fluid from the fluid reservoir 138 is pumped with the metering pump 118 through the preheater 116 and pressure sensor 120 before entering either the first expansion chamber 102 or the second expansion chamber 202. In the embodiments described herein a first valve 144 is disposed between the pressure sensor 120 and the liquid delivery conduit 106 such that liquid precursor material from the fluid reservoir 138 passes through the first valve 144 before entering the first expansion chamber 102. Similarly, a second valve 140 is disposed between the pressure sensor 120 and the liquid delivery conduit 206 such that liquid precursor material from the fluid reservoir 138 passes through the first valve 144 before entering the first expansion chamber 202. Accordingly, it should be understood that the first valve 144 and the second valve 140 may be utilized to control the flow of liquid precursor material from the fluid reservoir 138 to the first expansion chamber 102 and the second expansion chamber 202, including isolating the first or second expansion chambers 102, 202 from the fluid reservoir 138.

Similarly, the vapor delivery conduit 108 of the first expansion chamber 102 and the vapor delivery conduit 208 of the second expansion chamber 202 are fluidly coupled to a vapor feed conduit 310 with a third valve 142 and a fourth valve 146, respectively. The third valve 142 and fourth valve 146 can be used to control the flow of vaporized liquid precursor material from the first vaporizer chamber 102 and the second vaporizer chamber 202, respectively, to the burner 134. Accordingly, it should be understood that the flow of vaporized liquid precursor material from the first vaporizer chamber 102 and the second vaporizer chamber 202 can be shut off utilizing the third valve 142 and the fourth valve 146, respectively.

As noted hereinabove, the vaporizer 300 contains two expansion chambers 102, 202 which are oriented in parallel. Accordingly, either expansion chamber 102, 202 may be used to feed vapor precursor materials to the burner 134 through feed conduit 310 to create silica glass soot 309 for use in forming an optical fiber preform. Moreover, the vaporizer 300 can be operated with either the first expansion chamber 102 or the second expansion chamber 202 isolated from the fluid reservoir 138 and the feed conduit 310 to facilitate cleaning of the expansion chambers without having to discontinue the operation of the vaporizer 300.

The operation of the vaporizers to produce vaporized liquid precursor material for use in forming an optical fiber preform will now be described with specific reference to the vaporizer 100 shown in FIG. 1.

Referring to FIG. 1, when OMCTS is used as the liquid precursor material for formation of an optical fiber preform, a portion of the OMCTS liquid precursor has a tendency to form a gel as a byproduct of the vaporization process. While not being bound by theory, it is believed that the gel is formed, at least in part, due to uneven and/or excessive heating of the liquid phase precursor materials in the expansion chamber 102. Accordingly, the vaporizer is constructed and operated to minimize or eliminate “hot spots” in the expansion chamber which may lead to the formation of gel within the expansion chamber.

Moreover, the vaporizer is operated such that the gel byproduct that is formed in the expansion chamber and collected at the bottom of the expansion chamber is continuously flushed from the expansion chamber while the vaporizer is in operation, thereby reducing fouling of the expansion chamber due to the formation of the gel as well as mitigating the formation additional gel as a result of unvaporized OMCTS which pools in the lower region of the expansion chamber.

In particular, liquid precursor material, such as OMCTS, is pumped from the fluid reservoir 138 with the metering pump 118 through the preheater 116 and into the liquid delivery conduit 106. The liquid delivery conduit 106 forms the flow of liquid precursor material into a spray 150 which is directed at the vertical wall 104 of the expansion chamber 102. The vertical wall 104 of the expansion chamber is heated with the heating system 110 to a temperature sufficient to partially vaporize the liquid precursor material as the liquid precursor material contacts the vertical wall 104. Specifically, the vertical wall 104 is heated to a temperature such that a first portion of the liquid precursor material is vaporized while a second portion of the flow of liquid precursor material remains in a liquid state and a third portion of the liquid precursor material is formed into gel.

In one embodiment, as the pressure P inside the expansion chamber 102 increases due to gelling of various species contained in the liquid precursor material, the temperature of the vertical wall 104 of the expansion chamber is increased according to the following relation:

$$P = A exp ( - \frac{B}{T + D} ) ,$$

where T is the temperature in Kelvin of the expansion chamber, P is a pressure in atmospheres inside the expansion chamber, and A, B and D are empirically determined parameters that describe the vapor pressure of the species of OMCTS which is to be vaporized. Table 1 contains exemplary values for the parameters A, B, and D for different species which may be contained in the liquid precursor material. When the liquid precursor material includes a mixture of species, as described herein, the expansion chamber is operated at a temperature sufficient to vaporize the desired species (i.e., the species used to form vapor-phase reactants which can be pyrolized to form silica glass soot), while the remaining species remain in liquid form and/or gel and are collected at the lower portion of the expansion chamber 102. In particular, the temperature at which the expansion chamber 102 is operated can be determined using the equation above in conjunction with the parameters of a specific species from Table 1. Accordingly, by selecting the parameters for the species for which vaporization is desired, the appropriate operating temperature can be obtained and the expansion chamber 102 can then be heated to this temperature.

In one embodiment, determination of the desired operating temperature for vaporization of a specific species may be determined with control unit 124 based upon input from an operator. For example, in one embodiment the various parameters A, B, and D may be stored in a look up table (LUT) in a memory of the control unit 124 and, upon input of a desired species identifier into the control unit 124 by an operator, the control unit 124 controls the heating system 110 to achieve the desired temperature within the expansion chamber 102.

TABLE 1

| Species | D₃ | D₄ | D₅ | D₆ | D₇ | D₈ | D₉ |
|---|---|---|---|---|---|---|---|
| Parameter “A” | 20.606 | 20.453 | 20.318 | 20.412 | 20.269 | 20.273 | 20.36 |
| Parameter “B” | −3001.4 | −3128.5 | −3292 | −3572.2 | −3661.3 | −3817 | −3989.9 |
| Parameter “D” | −77.71 | −98.093 | −109.66 | −116.14 | −129.93 | −139.98 | −147.07 |

Once the appropriate temperature is determined to achieve vaporization of the desired species in the liquid precursor material, the vertical wall 104 of the expansion chamber 102 may be maintained at the desired temperature by controlling the heating system 110 with the control unit 124. In particular, the control unit receives a signal indicative of the temperature of the vertical wall 104 of the expansion chamber 102 and regulates the heating system 110 to maintain the temperature of the vertical wall 104 such that the aforementioned relationship is satisfied.

It has been determined that, heating the expansion chamber to a temperature which satisfies the aforementioned relationship reduces the formation of gel in the expansion chamber while, at the same time, intentionally increasing the amount of the liquid precursor material which is not vaporized (i.e., the amount of liquid precursor material which remains in the liquid state). Under conventional operating conditions increasing the amount of unvaporized liquid precursor material would be undesirable as the unvaporized material collects and pools in the lower region of the expansion chamber where it reacts with the gelled byproducts and forms more gel. However, the vaporizer 100 described herein is operated with drain 128 open throughout the vaporization process such that the expansion chamber 102 is continuously drained during the vaporization process. More particularly, as gel is collected in the lower region of the expansion chamber 102, the vertical wall 104 of the expansion chamber 102 is maintained at a temperature such that a sufficient amount of liquid precursor material (i.e., the second portion of the liquid precursor material) collects in the lower region of the expansion chamber 102 and is continuously drained from the expansion chamber so as to flush the gel (i.e., the third portion of the liquid precursor material) from the expansion chamber 102 thereby mitigating fouling of the expansion chamber. In some embodiments described herein the flow rate of the gel and un-vaporized liquid precursor material through drain 128 is less than about 10% of the flow rate of liquid precursor material being delivered through the delivery conduit 106. For example, in one embodiment the flow rate of the gel and un-vaporized liquid precursor material through the drain 128 is greater than or equal to about 0.1% and less than or equal to about 10% of the flow rate of the liquid precursor material delivered through the delivery conduit 106. In another embodiment, the flow rate of the gel and un-vaporized liquid precursor material flowing through the drain 128 is controlled by adjusting the temperature of the expansion chamber 102 with the heating system 110.

Moreover, as the liquid precursor material is vaporized, the stirring mechanism 114 is utilized to stir the vaporized liquid precursor material in the expansion chamber 102 such that the temperature of the vaporized liquid precursor material is uniform throughout the chamber, thereby avoiding any hot spots which may lead to gelation of the precursor material.

After the liquid precursor material is vaporized, the vapor is extracted from the expansion chamber 102 through the vapor delivery conduit 108. The vapor is fed to a burner 134 where the vapor is pyrolized in to glass soot and deposited on a bait rod to form a glass optical fiber preform.

To facilitate a complete flush of the expansion chamber 102, a nitrogen purge may be initiated in which nitrogen is fed into the expansion chamber and exhausted out through the drain 128 carrying with it any pooled and/or gelled OMCTS which may have collected in the lower portion of the expansion chamber 102.

It should be understood that the vaporizer 300 shown in FIG. 2 can be operated in a similar manner as the vaporizer 100 shown in FIG. 1. In particular, either the first expansion chamber 102 and/or the second expansion chamber 202 may be operated as described hereinabove to reduce the formation of gelling species in the expansion chamber.

It should now be understood that the methods and apparatuses described herein may be utilized to produce vapor phase materials from liquid precursor materials for use in forming an optical fiber preform. In particular, the methods described herein may be utilized to control the gelation of liquid precursor materials in a vaporizer and thereby reduce fouling of the vaporizer due to the formation of gel and/or pooling of the liquid precursor materials in the expansion chamber of the vaporizer. Moreover, operating a vaporizer according to the methods described herein allows for any pooled and/or gelled liquid precursor materials to be flushed from the expansion chamber of the vaporizer thereby mitigating formation of gel in the expansion chamber.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A method for vaporizing liquid precursor material for use in a vapor deposition process, the method comprising:
introducing a flow of liquid precursor material into an expansion chamber, a portion of the liquid precursor material being polymerizable to form a gel;
directing the flow of liquid precursor material towards a vertical wall of the expansion chamber;
heating the vertical wall of the expansion chamber to a temperature sufficient to vaporize a first portion of the flow of liquid precursor material while a second portion of the flow of liquid precursor material remains in a liquid state and a third portion of the liquid precursor material is formed into the gel;
collecting the gel at a lower region of the expansion chamber; and
continuously draining the expansion chamber as the flow of liquid precursor material is introduced into the expansion chamber, wherein a temperature of the expansion chamber is such that a sufficient amount of the second portion of the liquid precursor material is present in the liquid state to continuously flush the gel from the expansion chamber.

2. The method of claim 1, further comprising stirring the flow of liquid precursor material in the expansion chamber such that a temperature of the liquid precursor material is uniform in the expansion chamber.

3. The method of claim 1, further comprising:
monitoring the temperature of the expansion chamber; and
regulating a temperature of the expansion chamber such that:
$$P = A exp ( - \frac{B}{T + D} ) ,$$
wherein T is the temperature of the expansion chamber, P is a pressure inside the expansion chamber, and A, B and D are parameters that describe a vapor pressure of a species in the flow of the liquid precursor material to be vaporized.

4. The method of claim 1, wherein the second portion of the liquid precursor material is a siloxane having a boiling point greater than or equal to a boiling point of the first portion of the liquid precursor material.

5. The method of claim 4, wherein the first portion of the liquid precursor material is octamethylcyclotetrasiloxane.

6. The method of claim 5, wherein the second portion of the liquid precursor material is decamethylcyclopentasiloxane or dodecamethylcyclohexasiloxane.

7. The method of claim 5, wherein the siloxane is Dₙ, wherein D is ([(CH₃)₂Si]—O—) and n is greater than or equal to 7 and less than or equal to 40.

8. The method of claim 1, wherein a flowrate of material continuously draining from the expansion chamber is controlled by adjusting a temperature of the expansion chamber.

9. The method of claim 1, wherein a flowrate of material continuously draining from the expansion chamber is less than or equal to 10% of a flow rate of the flow of liquid precursor material into the expansion chamber.

10. The method of claim 1, wherein a thermal conductivity of the expansion chamber is greater than about 100 Btu/hr-ft-F to promote uniform heating of the expansion chamber.

11. A method for vaporizing liquid precursor material for use in a vapor deposition process, the method comprising:
introducing a flow of liquid precursor material into an expansion chamber, a portion of the liquid precursor material being polymerizable to form a gel;
directing the flow of liquid precursor material towards a wall of the expansion chamber;
heating the expansion chamber to a temperature sufficient to vaporize a first portion of the flow of liquid precursor material while a second portion of the flow of liquid precursor material remains in a liquid state and a third portion of the liquid precursor material is formed into the gel, the temperature satisfying a relationship:
$$P = A exp ( - \frac{B}{T + D} ) ,$$
wherein T is the temperature of the expansion chamber, P is a pressure inside the expansion chamber, and A, B and D are parameters that describe a vapor pressure of a species in the flow of the liquid precursor material to be vaporized.

12. The method of claim 11, further comprising:
collecting the gel at a lower region of the expansion chamber; and
continuously draining the second portion of the liquid precursor material present in the liquid state from the expansion chamber such that the gel is continuously flushed from the expansion chamber as the flow of liquid precursor material is introduced into the expansion chamber.

13. The method of claim 11, further comprising stirring the flow of liquid precursor material in the expansion chamber such that a temperature of the liquid precursor material is uniform in the expansion chamber.

14. The method of claim 11, wherein a thermal conductivity of the expansion chamber is greater than about 100 Btu/hr-ft-F to promote uniform heating of the expansion chamber.

15. A vaporizer for vaporizing liquid precursor material used in the formation of glass optical fiber preforms, the vaporizer comprising:
a first expansion chamber at least partially enclosed by a first vertical wall, the first expansion chamber formed from a material having a thermal conductivity of at least 100 BTU/hr-ft-F;
a first liquid delivery conduit positioned in the first expansion chamber, the first liquid delivery conduit directing a spray of liquid precursor materials onto the first vertical wall;
a first vapor delivery conduit coupled to the first expansion chamber, the first vapor delivery conduit extracting vaporized liquid precursor material from the first expansion chamber;
a first stirring apparatus disposed within the first expansion chamber, the first stirring apparatus stirring vaporized liquid precursor material such that a temperature of the vaporized liquid precursor material is uniform within the first expansion chamber; and
a heating system thermally coupled to the first vertical wall of the first expansion chamber, the heating system heating at least a portion of the first vertical wall to a temperature sufficient to vaporize the liquid precursor material.

16. The vaporizer of claim 15, further comprising a first drain positioned in a lower region of the first expansion chamber, the first drain continuously draining gel by-products and pooled liquid precursor materials from the first expansion chamber.

17. The vaporizer of claim 15, further comprising:
a temperature sensor thermally coupled to the first expansion chamber;
a control unit electrically coupled to the temperature sensor and the heating system, wherein the control unit comprises a processor and a memory storing computer readable instructions, the control unit executing the computer readable instructions to:
receive a temperature of the first expansion chamber; and
control the heating system such that the temperature of the first expansion chamber satisfies a relationship:
$$P = A exp ( - \frac{B}{T + D} ) ,$$
wherein T is the temperature of the first expansion chamber, P is a pressure inside the first expansion chamber, and A, B and D are parameters that describe a vapor pressure of a species in the flow of the liquid precursor material to be vaporized.

18. The vaporizer of claim 15, further comprising:
a second expansion chamber, at least partially enclosed by a second vertical wall, the second expansion chamber formed from a material having a thermal conductivity of at least 100 BTU/hr-ft-F;
a second liquid delivery conduit positioned in the second expansion chamber and fluidly coupled to the first liquid delivery conduit with a plurality valves such that the second liquid delivery conduit can be fluidly isolated from the first liquid delivery conduit, the second liquid delivery conduit directing a spray of liquid precursor materials onto the second vertical wall;
a second vapor delivery conduit coupled to the second expansion chamber and fluidly coupled to the second vapor delivery conduit with a plurality of valves such that the second expansion chamber can be isolated from the second vapor delivery conduit, the second vapor delivery conduit extracting vaporized liquid precursor material from the second expansion chamber;
a second stirring apparatus disposed within the second expansion chamber, the second stirring apparatus stirring the vaporized liquid precursor material such that a temperature of the vaporized liquid precursor material is uniform within the second expansion chamber; and
wherein, the second expansion chamber is thermally coupled to the heating system, the heating system heating at least a portion of the second vertical wall to a temperature sufficient to vaporize the liquid precursor material.

19. The vaporizer of claim 18, further comprising a second drain positioned in a lower region of the second expansion chamber, the second drain continuously draining gel by-products and pooled liquid precursor materials from the second expansion chamber.

20. The vaporizer of claim 18, further comprising a burner, wherein the first vapor delivery conduit and the second vapor delivery conduit are coupled to the burner, the burner pyrolizing the vaporized liquid precursor material into glass particulates.
